(19) United States
(12) Patent Application Publication
(10) Pub. No.: US 2007/0029543 A1
(43) Pub. Date: Feb. 8, 2007

(54) Semiconductor device

(75) Inventors: Hitoshi Ninomiya, Kanagawa (JP); Yoshinao Miura, Kanagawa (JP)

Correspondence Address: YOUNG & THOMPSON, 745 SOUTH 23RD STREET, 2ND FLOOR, ARLINGTON, VA, 22202, US

(73) Assignee: NEC ELECTRONICS CORPORATION, KANAGAWA (JP)

(21) Appl. No.: 11/497,342

(22) Filed: Aug. 2, 2006

(30) Foreign Application Priority Data
Aug. 4, 2005 (JP) 2005-227178

(51) Int. Cl. H01L 29/06

(52) U.S. Cl. 257/25

(57) ABSTRACT

To enhance the super-junction effect of a semiconductor device having the super-junction structure and prevent lowering in the breakdown voltage, a semiconductor device described herein has a first-conductivity-type substrate having an element forming region having a gate electrode and a source electrode formed therein, and a periphery region formed around the element forming region and having an element isolating region formed therein; and a parallel p-n layer having n-type drift regions and p-type column regions alternately arranged therein, formed along the main surface of the substrate, as extending from the element forming region to the periphery region, wherein, in the periphery region, a plurality of p-type column regions are provided outwardly from the element-forming region; and the gate electrode is a trench gate buried in the substrate, being formed so as to surround the p-type column regions also in the periphery region similarly to as in the element forming region.

This application is based on Japanese patent application No. 2005-227178 the content of which is incorporated hereinto by reference.

### BACKGROUND OF THE INVENTION

1. Field of the Invention

The present invention relates to a semiconductor device, and in particular to a semiconductor device having the super-junction structure.

2. Related Art

Vertical power MOSFET has been proposed as a high-voltage-type MOS field effect transistor (MOSFET). Critical characteristics of this sort of high-voltage MOSFET include ON-resistance and breakdown voltage. The ON-resistance and the breakdown voltage depend on resistivity of an electric field moderating layer, wherein a trade-off relation resides in that lowering in the resistivity by raising the impurity concentration of the electric field moderating layer successfully results in reduction in the ON-resistance, but also in lowering in the breakdown voltage at the same time.

In recent years, the super-junction structure has been proposed based on a technique of lowering the ON-resistance while keeping the breakdown voltage of high-voltage-type MOSFET unchanged.

FIG. 4 shows a configuration of a conventional semiconductor device having such super-junction structure.

A semiconductor device 10 includes a semiconductor substrate 11, an N-type drift region 14 which is formed on the semiconductor substrate 11 and which functions as an electric field moderating layer, a base region 15 formed on the N-type drift region 14, a source region 22 formed in the base region 15, a gate insulating film 20, a gate electrode 18 formed on the gate insulating film 20, an insulating film 24 formed on the gate electrode 18, a source electrode 26 formed on the insulating film 24, as being connected to the source region 22, a P-type column region 16 formed in the N-type drift region 14 between two adjacent portions of the gate electrode 18, and a drain electrode 12 formed on the back surface of the semiconductor substrate 11.

The semiconductor substrate 11, the N-type drift region 14 and the source region 22 herein have a same conductivity type (N-type in this case). The base region 15 and the P-type column region 16 have a conductivity type opposite to that of the N-type drift region 14 (P-type in this case). Dose of impurity is set to an almost same level both for the N-type drift region 14 and the P-type column region 16.

Operations is thus-configured semiconductor device will be explained below. When a reverse bias voltage is applied between the drain and the source under absence of the bias voltage between the gate and the source, depletion layers extend from two p-n junctions between the base region 15 and the N-type drift region 14, and between the P-type column region 16 and the N-type drift region 14, so that current does not flow between the drain and the source, and the device turns into the OFF state. More specifically, the interface between the P-type column region 16 and the N-type drift region 14 extends in the thickness-wise direction, and each depletion layer extends from the interface, so that depletion occurred to as wide as distance “d” shown in FIG. 4 results in depletion of the entire portion of the P-type column region 16 and the N-type drift region 14.

Therefore, if the P-type column region 16 and the N-type drift region 14 are specified so as to sufficiently shorter the distance “d”, the breakdown voltage of the semiconductor device 10 becomes no more dependent to the impurity concentration of the N-type drift region 14 which functions as the electric field moderating layer. As a consequence, adoption of the super-junction structure described in the above makes it possible to keep the breakdown voltage unchanged, while raising the impurity concentration of the N-type drift region 14 to thereby lower the ON-resistance. Japanese Laid-Open Patent Publication 2001-135819 discloses a super-junction semiconductor device having this sort of structure.

Japanese Laid-Open Patent Publication 2003-273355 (FIG. 1, FIG. 2) discloses a configuration of a semiconductor device having an N-type drift layer and a P-type drift layers formed not only in the cell region, but also to as far as the circumference of the junction end region. Of the junction end region, on the P-type drift layer in the vicinity of the interface with the cell region, a P-type base layer is formed. An insulating film is formed on the surface of the junction end region excluding a partial region located on the P-type base layer, a field electrode is formed on the insulating film so as to surround the cell region, so as to contact with the surface of the P-type base region, and so as to electrically connected to the source electrode. In other words, the field electrode is formed on the P-type drift region in the vicinity of the interface with the cell region, out of the junction end region.

### SUMMARY OF THE INVENTION

By the way, the more the inter-column-region pitch is narrowed, the more the super-junction effect is enhanced. In particular for devices having a low breakdown voltage between the drain and the source (typically up to 100 V), it is preferable to form a fine super-junction structure. However, despite every effort of narrowing the pitch of formation between the adjacent P-type column regions 16, any large thermal history applied thereafter allows the impurity in the P-type column regions 16 to diffuse into the N-type drift region 14 so as to expand the P-type column regions 16 in the transverse direction, so that narrowing of the pitch will be difficult.

It is, therefore, necessary for the semiconductor device having a fine super-junction structure to discuss fabrication processes unlikely to exert thermal history on the semiconductor device after the P-type column regions 16 is formed.

According to the present invention, there is provided a semiconductor device having a first-conductivity-type substrate having an element forming region having a gate electrode and a source electrode formed therein, and a periphery region formed around the element forming region; and

a parallel p-n layer having first-conductivity-type drift regions and second-conductivity-type column regions alternately arranged therein, formed along the main surface of the substrate, as extending from the element forming region to the periphery region,

wherein the gate electrode is a trench gate buried in the substrate, the trench gate being formed so as to surround the column regions in a plan view in the element forming region and the periphery region.

Fabrication procedures of the semiconductor device configured as having the N-type drift layers (N-type drift regions) and the P-type drift layers (P-type column regions) formed also in the junction end region, and having the field electrode formed thereon, as shown in Japanese Laid-Open Patent Publication 2003-273355, includes the followings:

(1) the P-type column regions are formed by ion implantation, and then the field electrode is formed thereon; and

(2) the field electrode is formed, and then ion implantation is carried out through the field electrode, to thereby form the P-type column regions.

As described in the above, for the semiconductor device having a fine super-junction structure, it is preferable to avoid exertion of any thermal history on the semiconductor device, after the P-type column regions were formed. The field electrode herein can be formed by depositing a polysilicon layer by the CVD process. Formation of the polysilicon layer by this process, however, exerts thermal history on the semiconductor device, so that the procedure (1) may cause diffusion of an impurity contained in the P-type column regions into the N-type drift regions during the formation of the field electrode, making it difficult to realize the fine super-junction structure.

It is, therefore, preferable to form the field electrode and then to form the P-type column regions as described in the procedure (2). FIG. 5 is a sectional view showing a configuration of a semiconductor device fabricated by forming the field electrode, and then by carrying out ion implantation through the field electrode to thereby form the P-type column regions.

A semiconductor device 50 has a semiconductor substrate 51; an N-type drift region 54 which is formed on the semiconductor substrate 51 and which functions as an electric field moderating layer; base regions 55 formed on the N-type drift region 54; source regions 62 formed on the base regions 55; a gate insulating film (not shown); a gate electrode 58 (and a connection electrode 58a connected to the gate electrode 58) formed on the gate insulating film; an insulating film 64 formed on the gate electrode 58; a source electrode 66 formed on the insulating film 64, as being connected to the source region 62; P-type column regions 56 formed between every two adjacent portions of the gate electrode 58 in the N-type drift region 54 (and P-type column regions 56a); a drain electrode 52 formed on the back surface of the semiconductor substrate 51; and an element isolating region 68. The semiconductor device 50 has also an element forming region having the gate electrode 58 formed therein, and a periphery region formed therearound. The semiconductor device 50 further has a field electrode 70 formed on the semiconductor substrate 51 in the periphery region. The field electrode 70 is electrically connected to the gate electrode 58 through the connection electrode 58a formed in the periphery region. The field electrode 70 herein is formed almost over the entire surface of the periphery region so as to make contact with the connection electrode 58a.

The P-type column regions 56 are formed by implanting a P-type impurity ion using a mask having a predetermined pattern opened on the semiconductor substrate 51. Because of presence of the already-formed field electrode 70, the impurity is introduced through the field electrode 70 in the periphery region by this ion implantation. The depth of the P-type column regions 56a is therefore shallower than the depth of the P-type column regions 56 in the element forming region. The super-junction effect depends also on the depth of the P-type column regions, showing a larger effect as the depth increases.

If the P-type column regions 56a in the periphery region are shallower than the P-type column regions 56 in the element forming region as shown in FIG. 5, the breakdown voltage of the periphery region becomes lower than the breakdown voltage of the element forming region, so that the breakdown voltage of the semiconductor device 50 as a whole is determined by the breakdown voltage of the periphery region. As a consequence, it is difficult that the breakdown voltage of the semiconductor device 50 as a whole is improved, even if the elements in the element forming region are fabricated by controlling various conditions aimed at raising the breakdown voltage. It is, therefore, necessary from this point of view, to fabricate the semiconductor device, so as to ensure the breakdown voltage in the periphery region not lower than that in the element forming region.

The semiconductor device of the present invention, having the column regions formed after the field electrode is formed, can prevent the semiconductor device from being exerted by thermal history after the column regions are formed. This is successful in forming the fine super-junction structure. Because the process is designed to form no field electrode in the periphery region, in particular on the region destined for forming therein the column regions, it is now possible, also in the periphery region, to form the column regions to a depth equivalent to or larger than the column regions in the element forming region. Lowering in the breakdown voltage of the periphery region is thus be avoidable.

Further, according to the present invention, there is provided a method of fabricating a semiconductor device, which contains a semiconductor substrate having an element forming region and a peripheral region adjoining said element forming region, said element forming region having a gate electrode, a first-conductivity-type source region and a second-conductivity-type base region, comprising:

forming a first-conductivity-type drift region in one surface of said semiconductor substrate,

forming a field electrode on said semiconductor substrate in a portion of said peripheral region;

forming a plurality of second-conductivity-type column regions in said first-conductivity-type drift region after forming said field electrode.

The present invention therefore makes it possible to enhance the super-junction effect of the semiconductor device having the super-junction structure, and to avoid lowering in the breakdown voltage.

### BRIEF DESCRIPTION OF THE DRAWINGS

The above and other objects, advantages and features of the present invention will be more apparent from the following description taken in conjunction with the accompanying drawings, in which:

FIGS. 1A and 1B are drawings showing a configuration of a semiconductor device in one embodiment;

FIGS. 2A and 2B are drawings showing states of arrangement of the p-type column regions;

FIGS. 3A to 3C are sectional views showing process steps of fabricating the semiconductor device in the embodiment;

FIG. 4 is a sectional view showing a configuration of a conventional semiconductor device having the super-junction structure; and

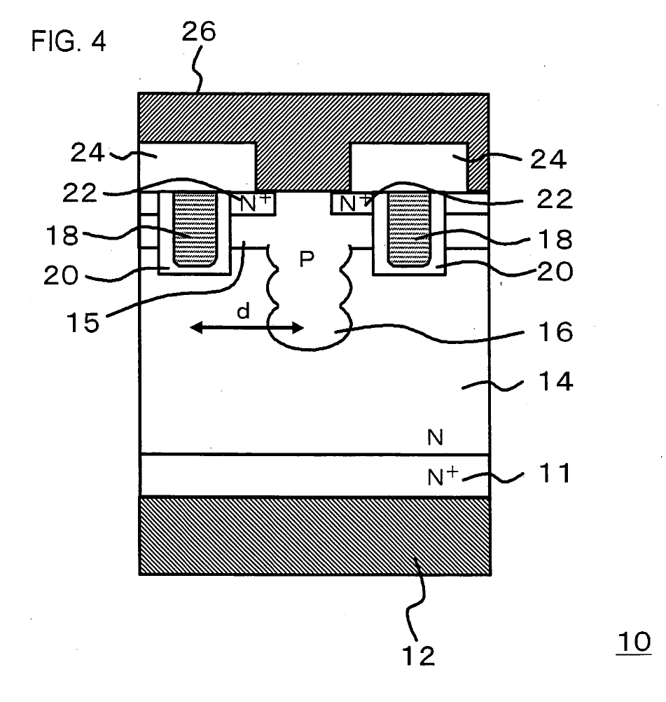

FIG. 5 is a sectional view showing a configuration of a semiconductor device obtained by forming the field electrode, and by implanting ion through the field electrode to thereby form the p-type column regions.

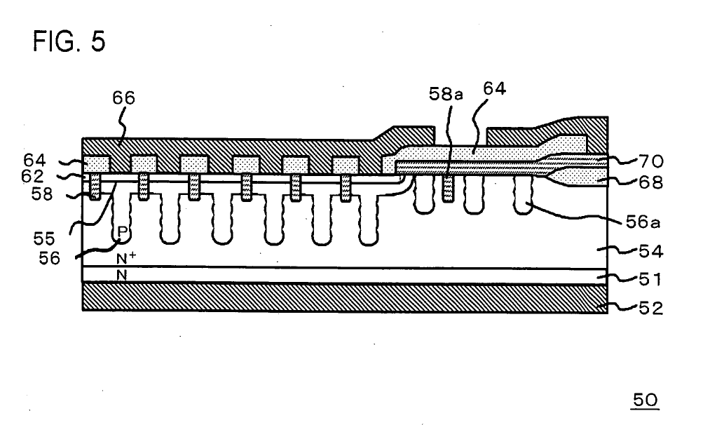

### DETAILED DESCRIPTION OF THE PREFERRED EMBODIMENT

The invention will be now described herein with reference to an illustrative embodiment. Those skilled in the art will recognize that many alternative embodiments can be accomplished using the teachings of the present invention and that the invention is not limited to the embodiment illustrated for explanatory purposes.

In the embodiment described below, any common constituents will be given with the same reference numerals, and the explanation will not be repeated. The embodiment below deals with the case where the first conductivity type is n-type, and the second conductivity type is p-type.

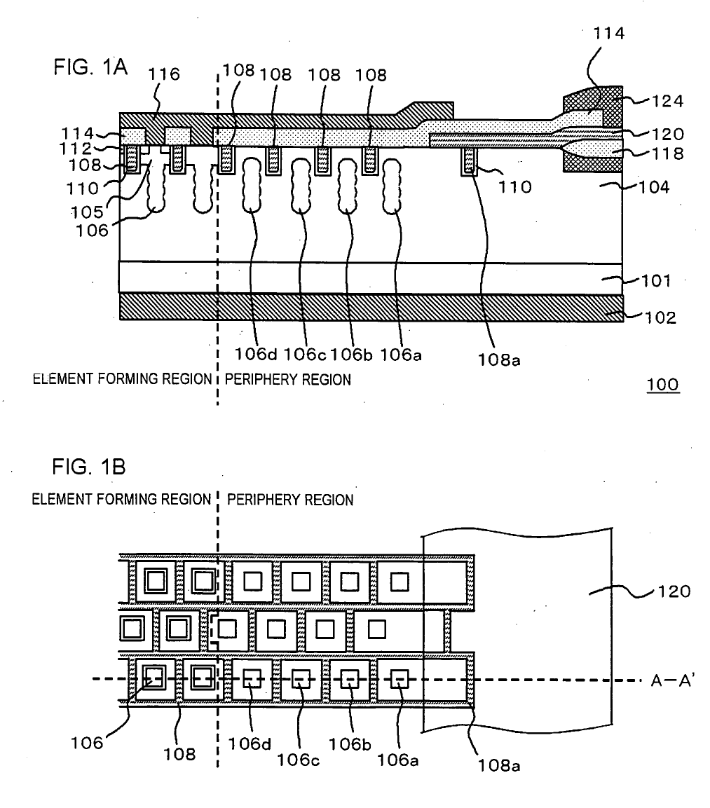

FIGS. 1A and 1B are drawings showing a configuration of the semiconductor device of this embodiment.

FIG. 1A is a sectional view showing a configuration of a semiconductor device 100 of this embodiment.

The semiconductor device 100 includes a trench-gate-type vertical power MOSFET. The semiconductor device 100 includes a first-conductivity-type substrate having an element forming region having a gate electrode 108 and a source electrode 116 formed therein, and a periphery region formed around the element forming region; and a parallel p-n layer having first-conductivity-type drift regions 104 and second-conductivity-type column regions 106 alternately arranged therein, formed along the main surface of the substrate, as extending from the element forming region to the periphery region, wherein the gate electrode 108 is a trench gate buried in the substrate, the trench gate being formed so as to surround the column regions 106a, 106b, 106c, 106d (referred to as “106a-d”, hereinafter) in a plan view in the element forming region and the periphery region.

The first-conductivity-type substrate herein is composed of a semiconductor substrate 101, and an n-type drift region 104 epitaxially grown thereon and functions as an electric field moderating layer. They are collectively referred to as “substrate”, hereinafter. On the main surface of the substrate, transistors connected to the source electrode 116 are formed as described later, and a drain electrode 102 is formed on the back surface.

In this embodiment, the gate electrode 108 is a trench gate buried in the substrate, and formed so as to surround the individual p-type column regions 106a-d formed in the periphery region in a plan view. A gate insulating film (for example, a gate oxidation film) 110 typically composed of a silicon oxide film is formed on the surface of the gate electrode 108 in the trench, and of the connection electrode 108a described later.

The semiconductor substrate 101, and the later-described n-type drift region 104 and the source region 112 have the same conductivity type (n-type in this case). The base region 105 and the p-type column regions 106, 106a-d have the conductivity type opposite to that of the n-type drift region 104 (p-type in this case). Dose of impurity is set to an almost same level both for the N-type drift region 104 and the P-type column regions 106, 106a-d.

The semiconductor device 100 has the element forming region having transistors formed therein, and the periphery region formed so as to surround the element forming region and has an element isolating region 118 formed therein. The p-type column regions 106, 106a-d are formed in the element forming region and in a part of the periphery region. From viewing of one aspect, a plural portions of the n-type drift region 104 (as the first-conductivity-type drift regions) of the parallel p-n layer are coupled together to be formed a reticular pattern. The semiconductor device 100 further includes a field electrode 120 formed in the periphery region, and an electrode 124 formed on the field electrode 120 in the periphery region. The field electrode 120 herein is typically composed of polysilicon, and generally has a function of a field plate electrode formed in the periphery region of elements of high-voltage semiconductor devices, and a function of a gate finger connecting the electrode 124 and the gate electrode 108. In this embodiment, there is no p-type column region formed straight under the field electrode 120.

In the periphery region, a connection electrode 108a as a gate interconnection pattern is formed in the outermost region of the gate electrode, and connected to the field electrode 120. The field electrode 120, being connected to the connection electrode 108a, is therefore electrically connected to the gate electrode 108 through the connection electrode 108a. In the periphery region, an insulating film 114 is formed on the field electrode 120.

In this embodiment, the periphery region has a plurality of p-type column regions 106a-d formed therein. Formation of the plurality of the p-type column regions in the periphery region is successful in keeping the breakdown voltage of the periphery region at a high level. In this embodiment, the p-type column region 106a-d formed in the periphery region has a depth substantially same with that of the p-type column regions 106 formed in the element forming region. In this embodiment, all of the p-type column regions 106, 106a-d have a substantially same impurity profile.

In the semiconductor device 100, p-type base regions 105, that is, having a second-conductivity-type, are formed along the main surface of the substrate as being surrounded by the trench-gate-type gate electrode 108 in the element forming region, but in the periphery region there is no p-type base region formed along the main surface of the substrate. In addition, high-concentration n-type (n⁺-type) source regions 112 are formed along the main surface of the p-type base regions 105 and around the gate electrode 108.

The source regions 112 are connected with the source electrode 116, so that the transistor composed of the source regions 112, the base regions 105, and the n-type drift regions 104 can be applied with voltage. The source electrode 116 is formed so as to cover, by the end portion thereof, the upper region of the p-type column regions 106a-d, that is a part of the periphery region. The source electrode 116 in the periphery region functions as a field plate, while allowing the insulating film 114 to function as the field insulating film, similarly to the field electrode 120.

In thus-configured element forming region, the base regions 105 can invert in the region along the gate electrode 108 under voltage applied through the gate electrode, and form channels. When voltage is further applied through the source electrode 116 to the source regions 112, that is, when the device is turned ON, current flows from the source regions 112 through the channels towards the n-type drift regions 104, to thereby make conduction between the source electrode 116 and the drain electrode 102. On the other hand, when there is no voltage applied through the source electrode 116, that is, when the device is turned OFF, depletion layers are formed at the interfaces between the p-type column regions 106 and the n-type drift regions 104, and thereby the source electrode 116 and the drain electrode 102 do not conduct. In this way, the semiconductor device 100 of this embodiment functions as a power MOSFET.

FIG. 1B is a top view showing a configuration of the semiconductor device 100 of this embodiment. For the convenience of explanation, the drawing shows only a configuration relevant to the p-type column regions 106, 106a-d, the gate electrode 108, the connection electrode 108a and the field electrode 120.

In this embodiment, the p-type column regions 106 are formed in a discrete manner, showing a rhombic lattice pattern in the two-dimensional arrangement. The field electrode 120 is provided in the periphery region, outside the outermost p-type column region 106a. The gate electrode 108 is electrically connected to the field electrode 120 through the connection electrode 108a formed in the periphery region. FIG. 1A herein shows the A-A′ section of FIG. 1B.

Although the p-type column regions 106, 106a-d were shown in FIG. 1B as having a rhombic lattice pattern, an orthogonal lattice pattern is also allowable. However, in view of allowing the effect of the super-junction structure to more distinctively exhibit, the two-dimensional arrangement is more preferably based on the rhombic lattice pattern, as described below.

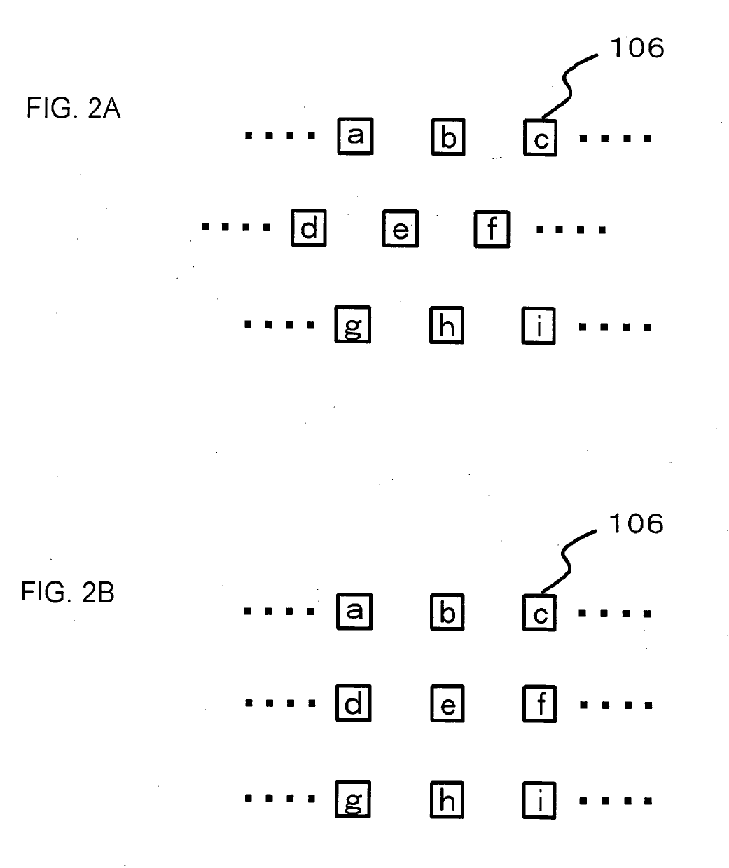

FIGS. 2A and 2B herein show states of arrangement of the p-type column regions.

FIG. 2A shows a state of arrangement of the p-type column regions 106, 106a to 106d of the semiconductor device 100 of this embodiment. The two-dimensional arrangement of the p-type column regions 106, 106a-d based on the rhombic lattice pattern can allow arrangement of such discrete p-type column regions 106, 106a-106d at regular intervals. On the other hand, in the arrangement of the p-type column regions based on the orthogonal lattice pattern showing in-line alignment both in the longitudinal direction and in the transverse direction as shown in FIG. 2B, the distance of, for example, p-type column region “e” measured from p-type column regions “b”, “d”, “f” and “h” differs from the distance of p-type column region “e” measured from the p-type column regions “a”, “c”, “g” and “i”. Arrangement of all of the discrete p-type column regions at regular intervals can equalize the distance between the p-type column regions 106 (106a-d) and the n-type drift regions 104 (see FIG. 1) over the entire region, and makes it possible to desirably exhibit the super-junction effect.

Paragraphs below will describe a method of fabricating a semiconductor device 100, which contains a semiconductor substrate having an element forming region and a peripheral region adjoining said element forming region, said element forming region having a gate electrode 108, a n-type source region 112 as a first-conductivity-type source region and a p-type base region 105 as a second-conductivity-type base region, of this embodiment.

The method contains forming a n-type drift region 104 as a first-conductivity-type drift region in one surface of the semiconductor substrate, forming a field electrode 120 on the semiconductor substrate in a portion of the peripheral region, and forming a plurality of second-conductivity-type column regions in the first-conductivity-type drift region after forming the field electrode 120.

Further, the method may contain forming a trench in the n-type drift region, and forming a gate insulating film 110 on a inner surface of the trench, wherein the gate electrode 108 is formed on the gate insulating film 110 in the trench and electrically connected with the field electrode 120.

Further, each of the plurality of p-type column regions 106a-d is surrounded by the gate electrode 108 in a plan view, respectively.

The concrete embodiment will be described as the following.

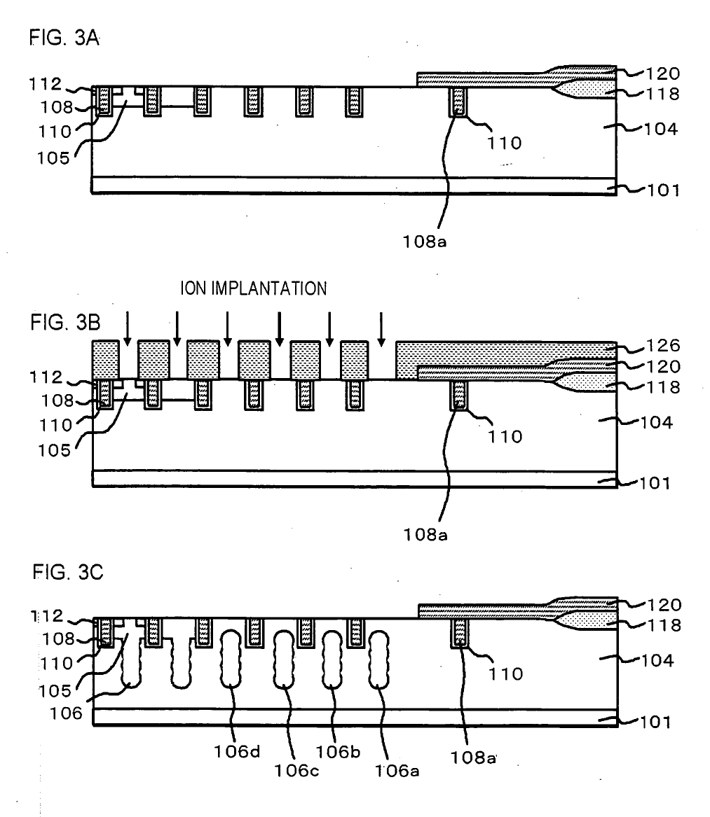

FIGS. 3A to 3C are sectional views showing process steps of fabricating the semiconductor device 100 of this embodiment.

First, on the main surface of the high-concentration, N-type semiconductor substrate 101, silicon is epitaxially grown, while being doped typically with phosphorus (P), to thereby form the n-type drift region 104. Next, in the periphery region, the element isolating region 118 is formed on the surface of the n-type drift region 104. The element isolating region 118 may be subjected to a LOCOS (local oxidation of silicon) process.

Next, boron (B) for example is doped by ion implantation into the surficial portion of the n-type drift region 104, to thereby form the base regions 105.

The surficial region of the n-type drift region 104 is then selectively etched with the aid of a photolithographic technique, to thereby form the trench. Next, the silicon oxide film is formed on the inner wall of the trench and on the surface of the N-type drift region 104 by thermal oxidation. A portion of the silicon oxide film formed on the top surface of the n-type drift region 104 is then removed, to thereby leave the silicon oxide film as the gate insulating film 110 on the inner wall of the trench. Next, a polysilicon layer is formed by the CVD (chemical vapor deposition) process in the trench and on the surface of the N-type drift region 104. The polysilicon layer is then selectively removed with the aid of a photolithographic technique, so as to leave it only on the surface of the gate insulating film in the trench and in a predetermined region of the surface of the substrate. As a consequence, the gate electrode 108, the connection electrode 108a, and the field electrode 120 are formed with a pattern as shown in FIG. 1B.

Next, arsenic (As) ion for example is implanted with the aid of a photolithographic technique to thereby form the high-concentration n-type (n⁺-type) source regions 112 in the surficial portion of the base regions 105 and around the gate electrode 108. By these procedures, a structure shown in FIG. 3A is formed.

Next, a mask 126 having a predetermined geometry is formed, and boron (B) ion for example is implanted through the mask into the n-type drift region 104 (FIG. 3B). The ion implantation herein may be divided into a plurality of times, under varied energy for each time. The mask 126 is then etched off (FIG. 3C). In this embodiment, the p-type column regions 106, 106a-d are formed to a depth not reaching the semiconductor substrate 101 which functions as the drain region.

Next, the insulating film 114 is formed on the surface of the n-type drift region 104, and then patterned according to a predetermined geometry. Next, an electrode layer is formed typically by sputtering using an aluminum target. The electrode layer is then patterned according to a predetermined geometry, to thereby form the source electrode 116 and the electrode 124. Also on the back surface of the semiconductor substrate 101, the drain electrode 102 is formed similarly by sputtering. By these procedures, the semiconductor device 100 having a structure as shown in FIG. 1A is obtained. In forming the field electrode 120, as shown in FIG. 1B, the field electrode 120 may be formed in an outer part from the outermost p-type column region 106a and electrically connected to the connection electrode 108a.

This embodiment is characterized by forming the field electrode 120 before the p-type column regions 106, 106a-d are formed, wherein there are no special limitations on other procedures such that, for example, the formation of which of the base regions 105, the source regions 112 and the field electrode 120 should precede the others. These constituents may be formed according to any procedures different from those described in the above.

This embodiment showed an exemplary case where the base regions were formed only in the region surrounded by the gate electrode 108 (trench gate) in the element forming region, whereas it is also allowable to form the base regions also in the regions surrounded by the gate electrode 108 in the periphery region, or in the region extending from the element forming region to the end portion of the field electrode 120 on the element forming region side.

This embodiment showed an exemplary case where the gate electrode 108 (trench gate) were formed so as to surround the individual p-type column regions 106a-d in the periphery region, and as being connected to the connection electrode 108a, whereas it is also allowable to form the trench-gate-type gate electrode so as to surround a part of the p-type column regions in the periphery region, and as being connected to the connection electrode 108a.

This embodiment showed an exemplary case where the depth of the p-type column regions 106a-d in the periphery region was equivalent to the depth of the p-type column regions 106 in the element forming region, whereas it is sufficient for the present invention that at least one of the p-type column regions 106a-d is provided with a depth not shallower than the p-type column regions 106, and in particular, the effect of the present invention can be obtained also by providing the outermost p-type column region 106a as being shallower than the other p-type column regions 106b-d. For example, it is also allowable to adjust the depth of the p-type column regions 106 formed in the element forming region and the outermost p-type column region 106a substantially equal to each other, and to make the p-type column regions 106b-d other than the outermost p-type column region 106a in the periphery region deeper than the p-type column regions 106 in the element-forming region. Also this configuration is successful in raising the breakdown voltage of the periphery region higher than the breakdown voltage of the element forming region. It is still also allowable to make the outermost p-type column region 106a shallower than the p-type column regions 106 formed in the element forming region, and to make the p-type column regions 106b-d other than the outermost p-type column region 106a formed in the periphery region deeper than the p-type column regions 106 formed in the element forming region. As has been described in the above, the depth of the P-type column regions in the individual regions of the element forming region and the periphery region may appropriately be set without departing from the spirit of the present invention.

The present invention has been described referring to the embodiment. The embodiment is merely an exemplary one, and those skilled in the art can readily understand that combinations of the individual constituents and process may be modified in various ways, and that also such modifications are within a scope of the present invention.

The above-described embodiment dealt with the case where the first conductivity type is n-type and the second conductivity type is p-type, whereas the first conductivity type may be p-type and the second conductivity type may be n-type.

A power MOSFET was explained in the above as an embodiment of an active element formed in the semiconductor device without limitation, and similar effect can be obtained also when the active element is configured, for example, as IGBT and gated thyristor.

It is apparent that the present invention is not limited to the above embodiment, that may be modified and changed without departing from the scope and spirit of the invention.

What is claimed is:

1. A semiconductor device comprising:
a first-conductivity-type substrate having an element forming region having a gate electrode and a source electrode formed therein, and a periphery region formed around said element forming region; and
a parallel p-n layer having first-conductivity-type drift regions and second-conductivity-type column regions alternately arranged therein, formed along the main surface of said substrate, as extending from said element forming region to said periphery region,
wherein said gate electrode is a trench gate buried in said substrate, said trench gate being formed so as to surround said column regions in a plan view in said element forming region and said periphery region.

2. The semiconductor device according to claim 1, wherein at least one of said column regions formed in the periphery region has a depth not smaller than the depth of the column regions formed in said element forming region.

3. The semiconductor device according to claim 1, wherein in said element forming region, a second-conductivity-type base region is formed in a region along the main surface of said substrate and surrounded by said trench gate, and
wherein in said periphery region, said second-conductivity-type base region is not formed in a region along the main surface of said substrate.

4. The semiconductor device according to claim 1, wherein said source electrode is formed so that the end portion thereof covers a part of said periphery region.

5. The semiconductor device according to claim 1, wherein the trench gate formed in said periphery region is formed so as to surround the individual column regions formed in said periphery region in a plan view.

6. The semiconductor device according to claim 1, wherein in said periphery region, a gate interconnection pattern is formed in the outermost region of said gate electrode, and
said trench gate is connected to said gate interconnection pattern.

7. The semiconductor device according to claim 1, wherein said first-conductivity-type drift regions of said parallel p-n layer are coupled together to be formed a reticular pattern.

8. A method of fabricating a semiconductor device, which contains a semiconductor substrate having an element forming region and a peripheral region adjoining said element forming region, said element forming region having a gate electrode, a first-conductivity-type source region and a second-conductivity-type base region, comprising:
forming a first-conductivity-type drift region in one surface of said semiconductor substrate,
forming a field electrode on said semiconductor substrate in a portion of said peripheral region,
forming a plurality of second-conductivity-type column regions in said first-conductivity-type drift region after forming said field electrode.

9. The method of fabricating a semiconductor device according to claim 8, further comprising:
forming a trench in said first-conductivity-type drift region; and
forming a gate insulating film on a inner surface of said trench,
wherein said gate electrode is formed on said gate insulating film in said trench and electrically connected with said field electrode.

10. The method of fabricating a semiconductor device according to claim 9, wherein each of said plurality of second-conductivity-type column regions is surrounded by said gate electrode in a plan view, respectively.
